(19) United States
(12) Patent Application Publication
(10) Pub. No.: US 2026/0052648 A1
(43) Pub. Date: Feb. 19, 2026

(54) THERMAL DIFFUSION DEVICE AND ELECTRONIC APPARATUS

(71) Applicant: Murata Manufacturing Co., Ltd., Nagaokakyo-shi (JP)

(72) Inventors: Tatsuhiro NUMOTO, Nagaokakyo-shi (JP); Masashi MORIKAMI, Nagaokakyo-shi (JP)

(21) Appl. No.: 19/367,054

(22) Filed: Oct. 23, 2025

Related U.S. Application Data
(63) Continuation of application No. PCT/JP2024/016012, filed on Apr. 24, 2024.

(30) Foreign Application Priority Data
Apr. 28, 2023 (JP) 2023-074588

(51) Int. Cl. H05K 7/20

(52) U.S. Cl. CPC H05K 7/20336

(57) ABSTRACT

A thermal diffusion device that includes: a housing having a first inner surface and a second inner surface facing each other in a thickness direction, the housing defining an internal space; a working medium in the internal space of the housing; and a wick in the internal space of the housing, wherein the wick has a plurality of through holes passing through the wick in the thickness direction thereof, the wick includes a plurality of hollow bump portions that extend toward the first inner surface of the housing in the thickness direction, at least one first through hole of the plurality of through holes is in one of the plurality of hollow bump portions, and a center-to-center distance of the plurality of hollow bump portions is larger than a center-to-center distance of the plurality of through holes.

### CROSS REFERENCE TO RELATED APPLICATIONS

The present application is a continuation of International application No. PCT/JP2024/016012, filed April 24, 2024, which claims priority to Japanese Patent Application No. 2023-074588, filed April 28, 2023, the entire contents of each of which are incorporated herein by reference.

### TECHNICAL FIELD

The present disclosure relates to a thermal diffusion device and an electronic apparatus.

### BACKGROUND ART

In recent years, elements have been highly integrated and have been improved in performance, thus increasing the amount of heat generated. In addition, size reductions of products increase the heat generation densities thereof. Thus, measures to dissipate heat are important. This situation is particularly conspicuous in the field of mobile terminals such as smart phones and tablets. For example, a graphite sheet is often used as a member for countermeasures against heat. However, the amount of heat transported thereby is not sufficient. Thus, use of various members for countermeasures against heat has been examined. In particular, use of vapor chambers, which are planar heat pipes and are thermal diffusion devices capable of diffusing heat significantly effectively, has been examined.

Such a vapor chamber has a structure in which a working medium (also referred to as a working liquid) and a wick configured to transport the working medium by capillary force are enclosed in a housing. The working medium absorbs heat from a heat generation element such as an electronic component in an evaporation portion configured to absorb heat from the heat generation element, evaporates in the vapor chamber, moves in the vapor chamber, and is cooled to return to a liquid phase. The working medium that has returned to the liquid phase is moved to the evaporation portion closer to the heat generation element again by the capillary force of the wick and cools the heat generation element. By repeating this operation, the vapor chamber is capable of operating autonomously without external power and of diffusing heat two-dimensionally at high speed by using evaporation latent heat and condensation latent heat of the working medium.

Patent Document 1 discloses a thermal ground plane, which is an example of the vapor chamber. The thermal ground plane described in Patent Document 1 includes a first planar substrate member, a plurality of micropillars disposed on the first planar substrate member, a mesh bonded on at least part of the micropillars, a vapor core disposed on at least one of the first planar substrate member, the micropillars, and the mesh, and a second planar substrate member disposed on the first planar substrate member. The mesh isolates the micropillars from the vapor core. The first planar substrate member and the second planar substrate member enclose the micropillars, the mesh, and the vapor core.

Patent Document 1: U.S. Patent No. 10,527,358

### SUMMARY OF THE DISCLOSURE

In such a vapor chamber described in Patent Document 1, a wick is formed by pillars such as micropillars and a porous body such as a mesh. For example, the pillars such as micropillars each have a quadrangular prism shape or a circular cylinder shape. A liquid passage for a working medium is formed between the pillars adjacent to each other.

However, the pillars provided for a liquid passage or a gas passage are generally bulk bodies. Thus, the surfaces of the pillars do not function as gas-liquid exchange surfaces. This may result in a reduction in the area of a driving portion of the vapor chamber.

The above problem is not limited to the vapor chamber and is a problem common to thermal diffusion devices capable of diffusing heat with a configuration similar to that of the vapor chamber.

The present disclosure is made to solve the above problem, and an object of the present disclosure is to provide a thermal diffusion device having a high heat dissipation effect by inhibiting a reduction in the area of a driving portion. In addition, another object of the present disclosure is to provide an electronic apparatus including the thermal diffusion device.

A thermal diffusion device according to the present disclosure includes: a housing having a first inner surface and a second inner surface facing each other in a thickness direction, the housing defining an internal space; a working medium in the internal space of the housing; and a wick in the internal space of the housing, wherein the wick has a plurality of through holes passing through the wick in the thickness direction thereof, the wick includes a plurality of hollow bump portions that extend toward the first inner surface of the housing in the thickness direction, at least one first through hole of the plurality of through holes is in one of the plurality of hollow bump portions, and a center-to-center distance of the plurality of hollow bump portions is larger than a center-to-center distance of the plurality of through holes.

An electronic apparatus according to the present disclosure includes the thermal diffusion device according to the present disclosure.

According to the present disclosure, it is possible to provide a thermal diffusion device having a high heat dissipation effect by inhibiting a reduction in the area of a driving portion. In addition, according to the present disclosure, it is possible to provide an electronic apparatus including the thermal diffusion device.

### BRIEF DESCRIPTION OF THE DRAWINGS

FIG. 1 is a schematic perspective view of an example of a thermal diffusion device according to a first embodiment of the present disclosure.

FIG. 2 is a schematic sectional view of an example of the thermal diffusion device according to the first embodiment of the present disclosure.

FIG. 3 is a schematic sectional view of examples of a housing and a wick that form the thermal diffusion device according to the first embodiment of the present disclosure.

FIG. 4 is a schematic plan view of an example of the wick illustrated in FIG. 3.

FIG. 5 is a schematic sectional view of an example of the shape of a projection 65.

FIG. 6 is a schematic sectional view of another example of the shape of the projection 65.

FIG. 7 is a schematic sectional view of still another example of the shape of the projection 65.

### DESCRIPTION OF THE PREFERRED EMBODIMENTS

A thermal diffusion device according to the present disclosure will be described below.

However, the present disclosure is not limited to the following embodiments, and modifications can be applied thereto as appropriate without changing the gist of the present disclosure. Combinations of two or more different preferable configurations of the present disclosure described below are also included in the present disclosure.

In the thermal diffusion device according to the present disclosure, a wick includes a plurality of hollow bump portions. Thus, similarly to the pillars described in Patent Document 1, it is possible to form a liquid passage for a working medium between the bump portions adjacent to each other.

In addition, in the thermal diffusion device according to the present disclosure, at least one of a plurality of through holes provided in the wick is provided in the bump portion. Thus, the surface of the bump portion of the wick is capable of functioning as a gas-liquid exchange surface. This inhibits a reduction in the area of a driving portion of the thermal diffusion device, thus enabling an increase in heat dissipation effect (mainly, maximum heat transfer rate Qmax).

It is needless to say that the embodiments described below are examples, and configurations of different embodiments can be partially replaced or combined. From a second embodiment, points in common with a first embodiment are not described, and only different points are described. In particular, similar operational effects resulting from similar configurations are not mentioned in each embodiment.

In the following description, when the embodiments are not particularly distinguished from each other, it is simply referred to as “thermal diffusion device according to the present disclosure”.

In the following description, a vapor chamber is taken as an embodiment of the thermal diffusion device according to the present disclosure. The thermal diffusion device according to the present disclosure is also applicable to thermal diffusion devices such as a heat pipe.

Figures described below are schematic, and, for example, the size or the aspect ratio thereof may differ from that of an actual product.

In the description, the terms representing the relationships between elements (such as “vertical”, “parallel”, and “orthogonal”) and the terms representing the shapes of the elements not only have strictly literal meanings but also have substantially equivalent meanings, for example, with a difference of about several percent.

### [First Embodiment]

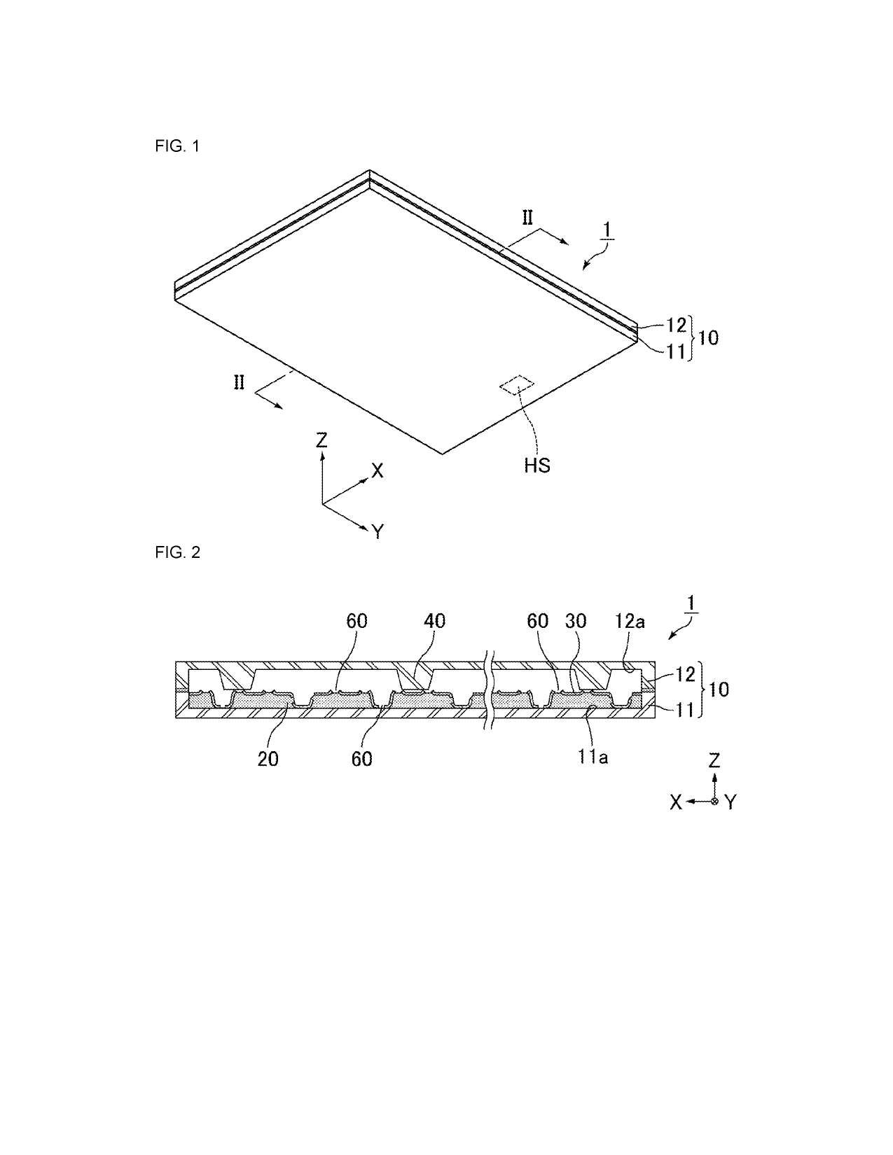

FIG. 1 is a schematic perspective view of an example of the thermal diffusion device according to the first embodiment of the present disclosure. FIG. 2 is a schematic sectional view of an example of the thermal diffusion device according to the first embodiment of the present disclosure. FIG. 2 is an example of a sectional view of the thermal diffusion device taken along line II-II in FIG. 1.

A vapor chamber (thermal diffusion device) 1 illustrated in FIGS. 1 and 2 includes a housing 10, which is hollow and is hermetically sealed. The housing 10 has a first inner surface 11a and a second inner surface 12a, which face each other in a thickness direction Z. The housing 10 has an internal space. The vapor chamber 1 further includes a working medium 20 enclosed in the internal space of the housing 10, and a wick 30 disposed in the internal space of the housing 10. The vapor chamber 1 may further include pillars 40 disposed in the internal space of the housing 10.

An evaporation portion configured to evaporate the enclosed working medium 20 is set in the housing 10. As illustrated in FIG. 1, a heat source HS, which is a heat generation element, is disposed on an outer surface of the housing 10. Examples of the heat source HS include electronic components of an electronic apparatus, such as a central processing unit (CPU). A part in the internal space of the housing 10 that is located in the vicinity of the heat source HS and that is configured to be heated by the heat source HS corresponds to the evaporation portion.

The vapor chamber 1 preferably has a planar shape as a whole. That is, the housing 10 preferably has a planar shape as a whole. Here, “planar shape” includes a plate-like shape and a sheet-like shape and means a shape in which the measurement in a width direction X (hereinafter referred to as the width) and the measurement in a length direction Y (hereinafter referred to as the length) are considerably larger than the measurement in the thickness direction Z (hereinafter referred to as the thickness or the height), for example, a shape in which the width and the length are 10 times or more, preferably 100 times or more, of the thickness.

The size of the vapor chamber 1, that is, the size of the housing 10 is not particularly limited. The width and the length of the vapor chamber 1 can be appropriately set according to its use. Each of the width and the length of the vapor chamber 1 is, for example, 5 mm to 500 mm, 20 mm to 300 mm, or 50 mm to 200 mm. The width and the length of the vapor chamber 1 may be equal to or different from each other.

The housing 10 is preferably formed by a first sheet 11 and a second sheet 12, which are joined at respective outer edge portions thereof and face each other.

When the housing 10 is formed by the first sheet 11 and the second sheet 12, the material forming the first sheet 11 and the second sheet 12 is not particularly limited as long as having characteristics, such as a thermal conductivity, a strength, elasticity, and flexibility, suitable for such a thermal diffusion device such as a vapor chamber. The material forming the first sheet 11 and the second sheet 12 is preferably a metal. Examples of such a metal include copper, nickel, aluminum, magnesium, titanium, iron, and alloys mainly composed of these metals. Particularly preferably, the material forming the first sheet 11 and the second sheet 12 is copper. The material forming the first sheet 11 may be the same as or different from the material forming the second sheet 12. Preferably, the material forming the first sheet 11 is the same as the material forming the second sheet 12.

When the housing 10 is formed by the first sheet 11 and the second sheet 12, the first sheet 11 and the second sheet 12 are joined at the respective outer edge portions thereof. The joining method is not particularly limited. Usable examples of such a joining method include laser welding, resistance welding, diffusion bonding, brazing, TIG welding (tungsten-inert gas welding), ultrasonic welding, and resin sealing. Preferably, it is possible to use laser welding, resistance welding, or brazing.

The thickness of the first sheet 11 and the thickness of the second sheet 12 are not particularly limited. Each of the thickness of the first sheet 11 and the thickness of the second sheet 12 is preferably 10 μm to 200 μm, more preferably 30 μm to 100 μm, even more preferably 40 μm to 60 μm. The thickness of the first sheet 11 and the thickness of the second sheet 12 may be equal to or different from each other. In addition, the thickness of each of the first sheet 11 and the second sheet 12 may be entirely uniform or partially thin.

The shape of the first sheet 11 and the shape of the second sheet 12 are not particularly limited. For example, each of the first sheet 11 and the second sheet 12 may be shaped such that the outer edge portion is thicker than the part thereof other than the outer edge portion.

The thickness of the entire vapor chamber 1 is not particularly limited and is preferably 50 μm to 500 μm.

The shape of the housing 10 in plan view when viewed in the thickness direction Z is not particularly limited. Examples of the shape of the housing 10 in plan view include a polygon such as a triangle or a rectangle, a circle, an ellipse, and shapes formed by combining these shapes. In addition, the shape of the housing 10 in plan view may be, for example, an L shape, a C shape (U shape), or a stepped shape. In addition, the housing 10 may have a through hole. The shape of the housing 10 in plan view may be a shape formed according to the use of a thermal diffusion device such as a vapor chamber, the shape of a part into which the thermal diffusion device is inserted, or other components located in the vicinity of the housing 10.

The working medium 20 is not particularly limited as long as being capable of changing between a gas phase and a liquid phase in the environment in the housing 10. Usable examples of the working medium 20 include water, alcohol, and alternative CFCs. For example, the working medium 20 is an aqueous compound, preferably water.

The wick 30 has a capillary structure capable of moving the working medium 20 by capillary force. The wick 30 preferably has a planar shape.

The material forming the wick 30 is not particularly limited and is preferably a metal. Examples of such a metal include copper, nickel, aluminum, magnesium, titanium, iron, and alloys mainly composed of these metals. Particularly preferably, the material forming the wick 30 is copper. The material forming the wick 30 may be the same as or different from the material forming the housing 10.

The size and the shape of the wick 30 are not particularly limited. For example, the wick 30 is preferably disposed continuously in the internal space of the housing 10. When viewed in the thickness direction Z, the wick 30 may be disposed in the entire internal space of the housing 10. When viewed in the thickness direction Z, the wick 30 may be disposed in part of the internal space of the housing 10.

The thickness of the wick 30 is not particularly limited and is, for example, 5 μm to 50 μm.

As illustrated in FIG. 2, the pillars 40 in contact with the second inner surface 12a may be disposed in the internal space of the housing 10. The disposition of the pillars 40 in the internal space of the housing 10 enables the housing 10 and the wick 30 to be supported.

The material forming the pillars 40 is not particularly limited. Examples of the material forming the pillars 40 include a resin, a metal, ceramic, and mixtures and laminates of these substances. In addition, as illustrated in FIG. 2, the pillars 40 may be integrally formed with the housing 10 and may be formed by, for example, subjecting the second inner surface 12a of the housing 10 to etching.

The shape of the pillars 40 is not particularly limited as long as the pillars 40 are shaped so as to be able to support the housing 10 and the wick 30. Examples of the shape of a section of the pillar 40 perpendicular to the height direction include a polygon such as a rectangle, a circle, and an ellipse.

As illustrated in FIG. 2, the pillar 40 may have a tapered shape in which the width of the pillar 40 narrows from the second inner surface 12a of the housing 10 toward the wick 30. Thus, it is possible to widen the part of a passage between the pillars 40 on the wick 30 side.

In the vapor chamber, each height of the pillars 40 may be equal or different. The height of the pillars 40 is, for example, 50 μm to 1000 μm.

The disposition of the pillars 40 is not particularly limited. The pillars 40 in a predetermined region are preferably evenly disposed, or more preferably all the pillars 40 are evenly disposed such that, for example, the center-to-center distance (pitch) of the pillars 40 adjacent to each other is uniform. The pillars 40 are evenly disposed, thus enabling the entire thermal diffusion device such as a vapor chamber to have a uniform strength. The center-to-center distance of the pillars 40 is, for example, 100 μm to 5000 μm.

In the section illustrated in FIG. 2, the width of the pillar 40 is not particularly limited as long as the pillar 40 has a strength sufficient to inhibit deformation of the housing 10. The equivalent circle diameter of a section perpendicular to the height direction of the end portion of the pillar 40 closer to the wick 30 is, for example, 100 μm to 2000 μm, preferably 300 μm to 1000 μm. An increase in the equivalent circle diameter of the pillar 40 enables deformation of the housing 10 to be further inhibited. On the other hand, a reduction in the equivalent circle diameter of the pillar 40 enables formation of a wider space for moving vapor of the working medium 20.

In the vapor chamber 1, the wick 30 has a plurality of through holes 60 passing through the wick 30 in the thickness direction Z.

Capillary action enables the working medium 20 to move in the through holes 60. The shape of the through holes 60 is not particularly limited. Preferably, a section of the through hole 60 perpendicular to the thickness direction Z is a circle or an ellipse.

The disposition of the through holes 60 is not particularly limited. The through holes 60 in a predetermined region are preferably evenly disposed, or more preferably all the through holes 60 are evenly disposed such that, for example, the center-to-center distance (pitch) of the through holes 60 adjacent to each other is uniform.

The through holes 60 can be formed by, for example, punching metal foil forming the wick 30 in press working.

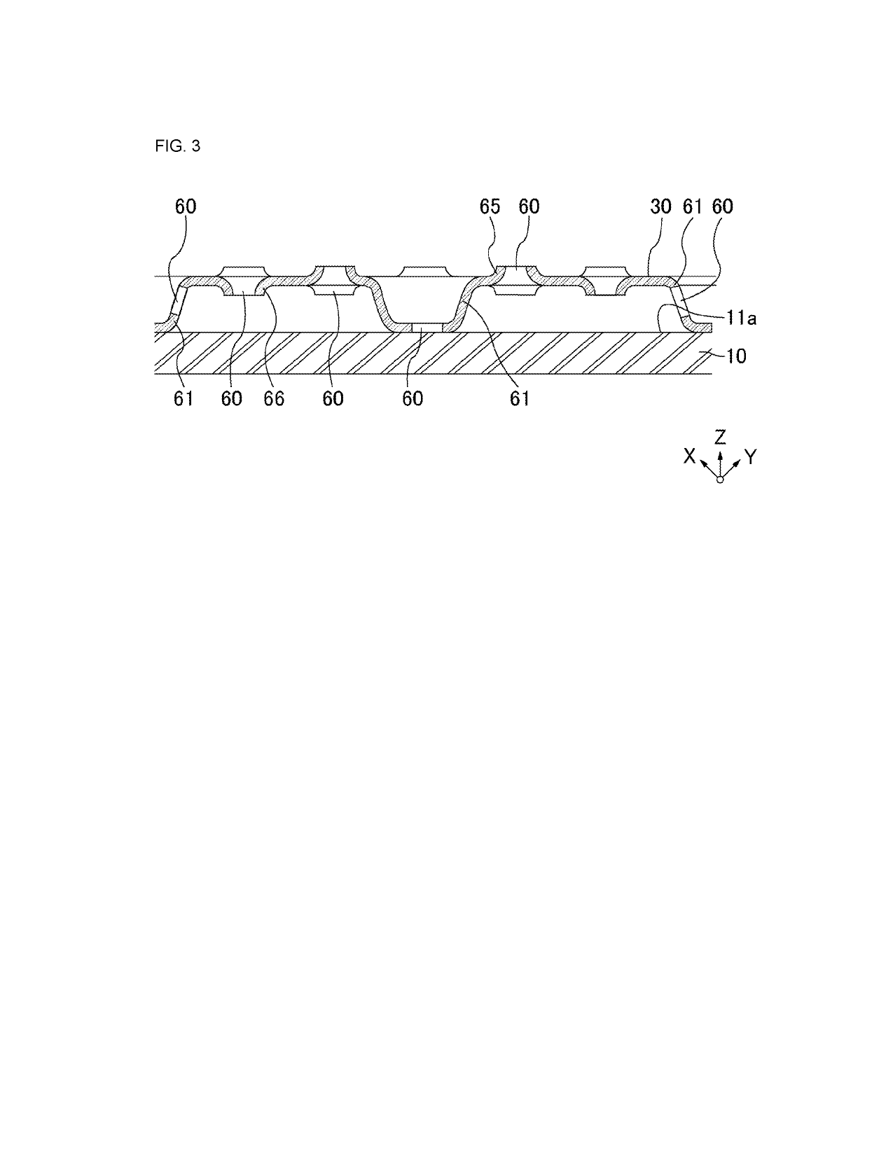

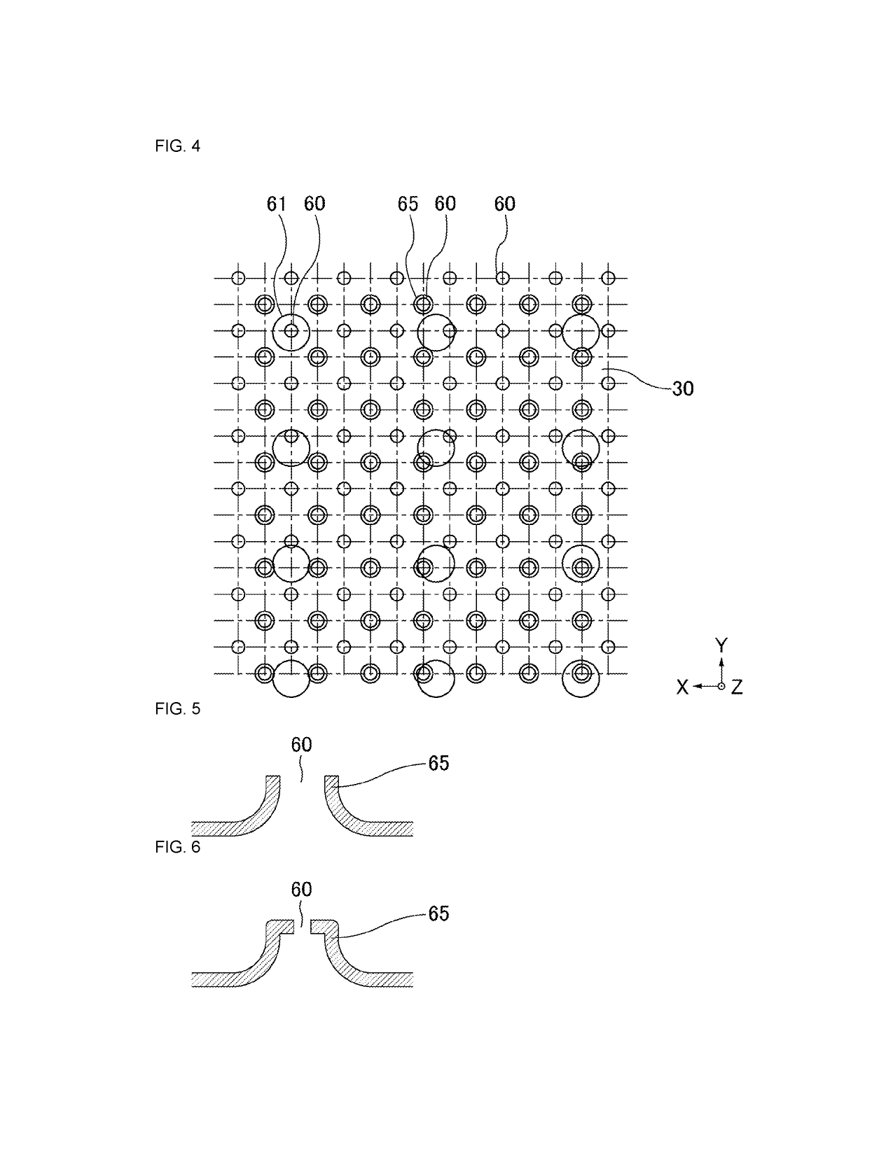

FIG. 3 is a schematic sectional view of examples of a housing and a wick that form the thermal diffusion device according to the first embodiment of the present disclosure. FIG. 4 is a schematic plan view of an example of the wick illustrated in FIG. 3.

As illustrated in FIGS. 3 and 4, the wick 30 includes a plurality of bump portions 61 extending toward the first inner surface 11a of the housing 10 in the thickness direction Z. The bump portion 61 has a hollow shape having a cavity. The bump portion 61 is formed by recessing part of the wick 30.

At least one of the plurality of through holes 60 is provided in one of the plurality of bump portions 61. The number of the bump portions 61 having the through holes 60 is not particularly limited and may be one or two or more. In addition, the bump portions 61 having no through holes 60 may be included.

For example, the number, position, size, and shape of the through holes 60 provided in the bump portions 61 are not particularly limited. For example, the wick 30 may include the bump portion 61 having one through hole 60 or may include the bump portion 61 having a plurality of through holes 60. In addition, the through hole 60 may be provided in a tip end surface of the bump portion 61 or may be provided in a side surface of the bump portion 61. FIG. 4 illustrates an example in which the plurality of bump portions 61 are disposed in a rectangular grid pattern. However, the disposition of the bump portions 61 is not limited thereto. For example, the bump portions 61 may be disposed in a zigzag pattern so as to be located at the vertices of regular triangles.

In addition, at least one of the plurality of through holes 60 may be provided in a part other than the bump portions 61. In this case, the number of the through holes 60 provided in parts other than the bump portions 61 may be equal to, smaller than, or larger than the number of the through holes 60 provided in the bump portions 61.

When the through hole 60 is provided in a part other than the bump portions 61, the shape of the through hole 60 provided in the part other than the bump portions 61 may be the same as or different from the shape of the through hole 60 provided in the bump portion 61.

When the through hole 60 is provided in a part other than the bump portions 61, the size of the through hole 60 provided in the part other than the bump portions 61 may be the same as or different from the size of the through hole 60 provided in the bump portion 61.

The bump portions 61 may be in contact with the first inner surface 11a of the housing 10 or do not have to be in contact with the first inner surface 11a of the housing 10. When the bump portions 61 are in contact with the first inner surface 11a, the bump portions 61 may be joined to the first inner surface 11a or do not have to be joined to the first inner surface 11a.

For example, the bump portions 61 include a plurality of pillar-shaped members. Here, “pillar shape” means a shape in which the length of the long sides of the bottom surface is less than five times of the length of the short sides of the bottom surface.

Alternatively, the bump portions 61 may include a plurality of rail-shaped members. Here, “rail shape” means a shape in which the length of the long sides of the bottom surface is five times or more of the length of the short sides of the bottom surface.

The working medium 20 in a liquid phase is held between the bump portions 61. Thus, it is possible to improve the heat transport performance of a thermal diffusion device such as a vapor chamber.

When the bump portions 61 include a plurality of pillar-shaped members, the shape of the bump portions 61 is not particularly limited. Examples of the shape of the bump portions 61 include a circular cylinder, an elliptic cylinder, a prism, a truncated cone, and a truncated pyramid.

When the bump portions 61 include a plurality of rail-shaped members, the shape of a section of the bump portion 61 perpendicular to the direction in which the bump portion 61 extends is not particularly limited. Examples of the sectional shape include a polygon such as a quadrilateral, a semicircle, a semiellipse, and shapes formed by combining these shapes.

As illustrated in FIG. 3, the bump portion 61 may have a tapered shape in which the width of the bump portion 61 narrows toward the first inner surface 11a of the housing 10. Thus, it is possible to widen the part of a passage between the bump portions 61 on the housing 10 side.

In the vapor chamber, each height of the bump portions 61 may be equal or different. The height of the bump portion 61 is, for example, 10 μm to 100 μm. The height of the bump portion 61 is preferably smaller than the height of the pillar 40.

The disposition of the bump portions 61 is not particularly limited. The bump portions 61 in a predetermined region are preferably evenly disposed, or more preferably all the bump portions 61 are evenly disposed such that, for example, the center-to-center distance (pitch) of the bump portions 61 adjacent to each other is uniform.

The center-to-center distance of the bump portions 61 is, for example, 60 μm to 800 μm. The center-to-center distance of the bump portions 61 is preferably smaller than the center-to-center distance of the pillars 40.

The equivalent circle diameter of a section perpendicular to the height direction of the end portion of the bump portion 61 closer to the wick 30 is, for example, 20 μm to 500 μm. The equivalent circle diameter of a section perpendicular to the height direction of the end portion of the bump portion 61 closer to the wick 30 is preferably smaller than the equivalent circle diameter of a section perpendicular to the height direction of the end portion of the pillar 40 closer to the wick 30.

The method for forming the bump portions 61 is not particularly limited. For example, parts of the metal foil forming the wick 30 are bent and recessed by working such as press working. Thus, it is possible to form the hollow bump portions 61 at the recessed parts. A vapor space is formed in each of the recessed parts in the bump portions 61, thus improving the thermal conductivity.

For example, working for forming the bump portions 61 is performed after performing press working for forming the through holes 60. Thus, it is possible to provide the through holes 60 in the bump portions 61 and to provide the through holes 60 in parts other than the bump portions 61. Alternatively, press working for forming the bump portions 61 and press working for forming the through holes 60 may be performed together.

When press working is performed on metal foil, depending on the press working conditions, the through holes 60 may be formed in the parts (that is, the bump portions 61) recessed when bending parts of the metal foil.

The thickness of metal foil yet to be subjected to working such as press working is preferably uniform. However, bent parts of the metal foil may be thin. Thus, in the example illustrated in FIG. 3, preferably, the thickness of the bump portions 61 is equal to the thickness of the part of the wick 30 other than the bump portions 61 or is smaller than the thickness of the part of the wick 30 other than the bump portions 61.

As illustrated in FIGS. 3 and 4, the center-to-center distance of the plurality of bump portions 61 is larger than the center-to-center distance of the plurality of through holes 60. The center-to-center distance of the through holes 60 is, for example, 3 μm to 150 μm.

The diameter of each of the through holes 60 is, for example, 100 μm or less. When the through holes 60 have different diameters when viewed in the thickness direction Z, the diameter of the smallest one of the through holes 60 is defined as the diameter of the through hole 60.

When the through hole 60 is provided in a part other than the bump portions 61, as illustrated in FIG. 3, a projection 65 or a projection 66, whose height is smaller than that of the bump portions 61, may be provided at the periphery of the through hole 60 provided in the part other than the bump portions 61. The provision of the projection 65 or the projection 66 at the periphery of the through hole 60 improves the performance of the wick 30.

Specifically, the projection 65 projecting toward the second inner surface 12a of the housing 10 (upward in FIG. 3) or the projection 66 projecting toward the first inner surface 11a of the housing 10 (downward in FIG. 3) may be provided at the periphery of the through hole 60 provided in the part other than the bump portions 61. One or both of the projection 65 and the projection 66 may be provided. In addition, the through hole 60 around which neither of the projections is provided may be included in a part other than the bump portions 61.

The projection 65 or the projection 66 may be provided only at part of the periphery of the through hole 60 but is preferably provided at the entire periphery of the through hole 60.

The projection 65 or the projection 66 can be formed by, for example, punching metal foil forming the wick 30 in press working. In this case, the projection 65 or the projection 66 may be formed simultaneously with the through hole 60 or may be formed separately from the through hole 60. In the punching process in press working, for example, the shape of the projection 65 or the projection 66 can be adjusted by appropriately adjusting the punching depth or the like. The punching depth means, for example, the depth of a punch pushed in a punching direction when the punching process is performed by using the punch.

The size of the projection 65 or the projection 66 is not particularly limited. For example, the height of the projection 65 or the projection 66 may be larger than the diameter of the through hole 60, may be smaller than the diameter of the through hole 60, or may be equal to the diameter of the through hole 60.

The shape of the projection 65 is not particularly limited.

FIG. 5 is a schematic sectional view of an example of the shape of the projection 65.

As illustrated in FIG. 5, in the section in the thickness direction, the distance across the outer wall of the projection 65 may be reduced in a direction toward the second inner surface of the housing (upward in FIG. 5). In this case, in the section in the thickness direction, the projection 65 may be shaped so as to project toward the second inner surface of the housing (upward in FIG. 5) or the first inner surface of the housing (downward in FIG. 5).

Alternatively, in the section in the thickness direction, the distance across the outer wall of the projection 65 may be increased in the direction toward the second inner surface of the housing. In this case, in the section in the thickness direction, the projection 65 may be shaped so as to project toward the second inner surface of the housing or the first inner surface of the housing.

FIG. 6 is a schematic sectional view of another example of the shape of the projection 65.

As illustrated in FIG. 6, the projection 65 may include a cover portion narrowing the through hole 60 at a tip end surface of the projection 65.

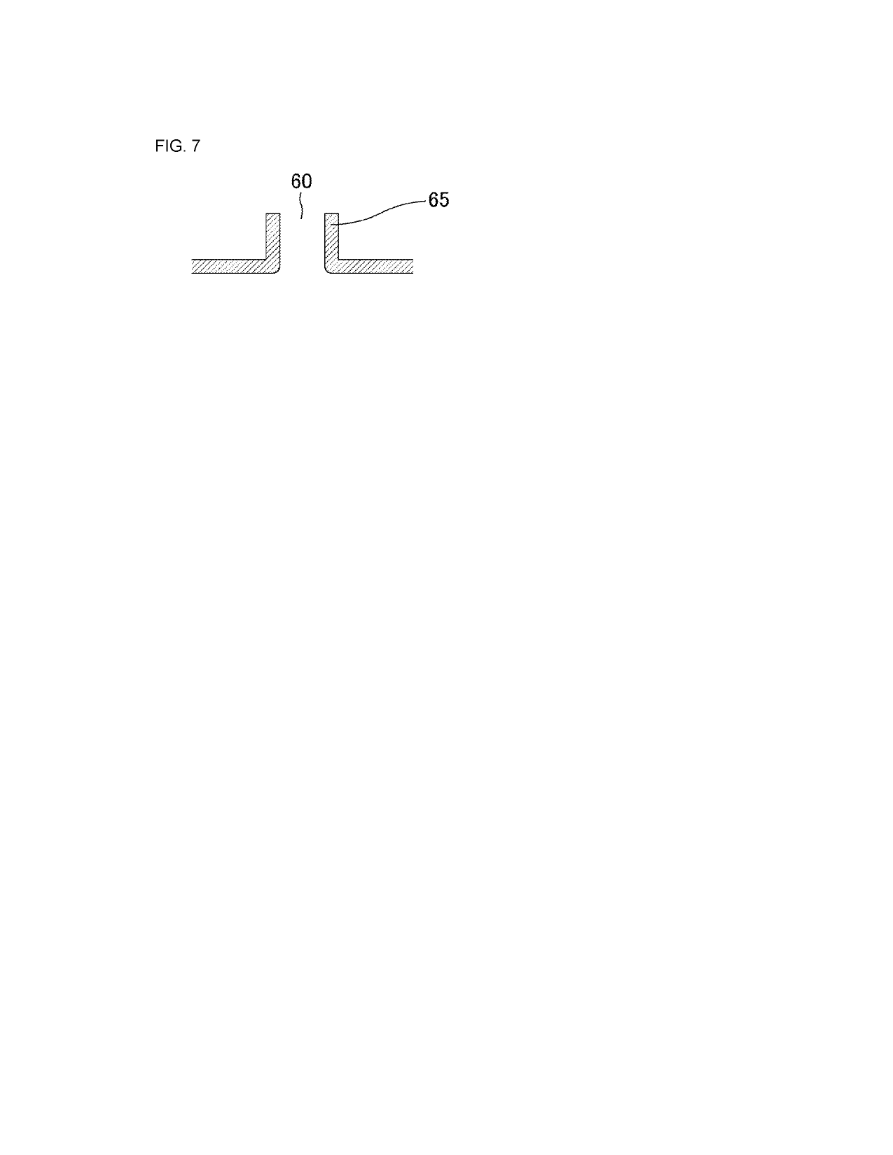

FIG. 7 is a schematic sectional view of still another example of the shape of the projection 65.

As illustrated in FIG. 7, in the section in the thickness direction, the distance across the outer wall of the projection 65 may be uniform in the direction toward the second inner surface of the housing (upward in FIG. 7). In this case, the projection 65 may include the cover portion narrowing the through hole 60 at the tip end surface of the projection 65.

Similarly, the shape of the projection 66 is not particularly limited. For example, in the section in the thickness direction, the distance across the outer wall of the projection 66 may be reduced or increased in a direction toward the first inner surface of the housing. In these cases, in the section in the thickness direction, the projection 66 may be shaped so as to project toward the second inner surface of the housing or the first inner surface of the housing. Alternatively, in the section in the thickness direction, the distance across the outer wall of the projection 66 may be uniform in the direction toward the first inner surface of the housing. In addition, the projection 66 may include a cover portion narrowing the through hole 60 at a tip end surface of the projection 66.

### [Other Embodiments]

The thermal diffusion device according to the present disclosure is not limited to the above embodiments. Various applications and modifications can be made to, for example, the configuration and the manufacturing conditions of the thermal diffusion device within the scope of the present disclosure.

In the thermal diffusion device according to the present disclosure, the housing may include one or a plurality of evaporation portions. That is, one or a plurality of heat sources may be disposed on the outer wall surface of the housing.

In the thermal diffusion device according to the present disclosure, when the housing is formed by the first sheet and the second sheet, the first sheet and the second sheet may overlap such that end portions thereof coincide or do not coincide with each other.

In the thermal diffusion device according to the present disclosure, when the housing is formed by the first sheet and the second sheet, the material forming the first sheet and the material forming the second sheet may be different from each other. For example, use of a material having a high strength for the first sheet enables the stress applied to the housing to be dispersed. In addition, use of different materials for the respective sheets enables one of the sheets to have one function and the other of the sheets to have another function. Such functions are not particularly limited. Examples of such functions include a thermal conduction function and an electromagnetic shielding function.

The thermal diffusion device according to the present disclosure can be mounted in an electronic apparatus to dissipate heat. Thus, the present disclosure also includes an electronic apparatus including the thermal diffusion device according to the present disclosure. Examples of the electronic apparatus according to the present disclosure include a smart phone, a tablet terminal, a notebook computer, a game device, and a wearable device. As described above, the thermal diffusion device according to the present disclosure is capable of operating autonomously without external power and of diffusing heat two-dimensionally at high speed by using evaporation latent heat and condensation latent heat of a working medium. Thus, the electronic apparatus including the thermal diffusion device according to the present disclosure is capable of effectively dissipating heat in a limited space in the electronic apparatus.

The thermal diffusion device according to the present disclosure can be used for various purposes in the field of, for example, portable information terminals. For example, the thermal diffusion device according to the present disclosure can be used to reduce the temperature of a heat source such as a CPU and to extend the operating time of an electronic apparatus and can be used for smart phones, tablet terminals, notebook computers, and the like.

### Reference Signs List

1 vapor chamber (thermal diffusion device)

10 housing

11 first sheet

11a first inner surface

12 second sheet

12a second inner surface

20 working medium

30 wick

40 pillar

60 through hole

61 bump portion

65, 66 projection

HS heat source

X width direction

Y length direction

Z thickness direction

CLAIMS

1. A thermal diffusion device comprising:
a housing having a first inner surface and a second inner surface facing each other in a thickness direction, the housing defining an internal space;
a working medium in the internal space of the housing; and
a wick in the internal space of the housing, wherein
the wick has a plurality of through holes passing through the wick in the thickness direction thereof,
the wick includes a plurality of hollow bump portions that extend toward the first inner surface of the housing in the thickness direction,
at least one first through hole of the plurality of through holes is in one of the plurality of hollow bump portions, and
a center-to-center distance of the plurality of hollow bump portions is larger than a center-to-center distance of the plurality of through holes.

2. The thermal diffusion device according to claim 1, wherein at least one second through hole of the plurality of through holes is in a part of the wick other than the plurality of hollow bump portions.

3. The thermal diffusion device according to claim 2, wherein a projection having a height smaller than a height of the plurality of hollow bump portions is located at a periphery of the second through hole in the part of the wick other than the plurality of hollow bump portions.

4. The thermal diffusion device according to claim 3, wherein a distance across an outer wall of the projection reduces in a direction toward a tip end surface of the projection.

5. The thermal diffusion device according to claim 3, wherein a distance across an outer wall of the projection is uniform in a direction toward a tip end surface of the projection.

6. The thermal diffusion device according to claim 3, wherein the projection includes a cover portion narrowing the through hole at a tip end surface of the projection.

7. The thermal diffusion device according to claim 1, wherein the one of the plurality of bump portions having the at least one first through hole has a tapered shape in which a width of the one of the plurality of bump portions narrows toward the first inner surface of the housing.

8. The thermal diffusion device according to claim 1, wherein the one of the plurality of bump portions has a single first through hole.

9. The thermal diffusion device according to claim 1, wherein the one of the plurality of bump portions has two or more of the first through holes.

10. The thermal diffusion device according to claim 1, further comprising at least one pillar in the internal space of the housing and extending in a direction from the second inner surface toward the wick.

11. The thermal diffusion device according to claim 1, wherein a section of the plurality of through holes perpendicular to the thickness direction is a circle or an ellipse.

12. The thermal diffusion device according to claim 1, wherein the plurality of through holes in a predetermined region of the wick are evenly disposed.

13. The thermal diffusion device according to claim 1, wherein the plurality of bump portions are in contact with the first inner surface of the housing.

14. The thermal diffusion device according to claim 1, wherein the plurality of bump portions in a predetermined region of the wick are evenly disposed.

15. An electronic apparatus comprising the thermal diffusion device according to claim 1.
